(19) United States
(12) Patent Application Publication
(10) Pub. No.: US 2019/0145714 A1
(43) Pub. Date: May 16, 2019

(54) METHOD FOR PREPARING POROUS WICK AND PRODUCT PREPARED BY THE SAME

(71) Applicant: Delta Electronics (Jiangsu) Ltd., Wujiang (CN)

(72) Inventors: Quanyao YU, Wujiang (CN); BOR-LIN LEE, Wujiang (CN); Chih-Ping WANG, Wujiang (CN); Chun-Lung CHIU, Wujiang (CN)

(73) Assignee: Delta Electronics (Jiangsu) Ltd., Wujiang (CN)

(21) Appl. No.: 15/956,725

(22) Filed: Apr. 18, 2018

(30) Foreign Application Priority Data
Nov. 16, 2017 (CN) 201711137877.5

(51) Int. Cl. F28D 15/04; C25D 3/38; C25D 5/10; C25D 5/34; C25D 7/00; H05K 7/20

(52) U.S. Cl. CPC F28D 15/046; C25D 3/38; H05K 7/20336; C25D 5/34; C25D 7/00; C25D 5/10

(57) ABSTRACT

The disclosure provides a method for preparing a porous wick, including the steps of: a) preparing an first electrolyte, which is an aqueous solution including 0.5-1.8 mol/L sulfuric acid and 0.1-0.5 mol/L copper sulfate; b) preparing a second electrodeposition electrolyte, which is an aqueous solution including 0.2-0.9 mol/L sulfuric acid and 0.4-0.9 mol/L copper sulfate; c) cleaning the surface of a metal substrate with a mixed solution of a surfactant and a basic compound, activating with dilute hydrochloric acid, and then rinsing; and d) carrying out a first elctrodeposition on the treated substrate in the first electrodeposition electrolyte, and then carrying out the second electrodeposition in the second electrodeposition electrolyte, wherein the second electrodeposition current density is smaller than the first electrodeposition current density. The porous structure of the disclosure with the specific arrangement, excellent capillary force and permeability is good for the transmission of the working liquid.

### CROSS REFERENCE

This application is based upon and claims priority to Chinese Patent Application No. 201711137877.5, filed on Nov. 16, 2017, the entire contents thereof are incorporated herein by reference.

### TECHNICAL FIELD

The disclosure relates to a porous wick structure of a vapor chamber, and particularly to a porous wick with thoughholes of a vapor chamber prepared by the soft template method and a method for preparing the same.

### BACKGROUND

With the development of science and technology, electronic products tend to be miniaturized. As the functions of electronic products become more and more, heat-generating and dissipating components are more and more concentrated in a smaller area. Therefore, the heat dissipation of electronic products is an important issue that must be considered in the process of product design and assembly.

The heat-dissipating components depending on the phase change such as a heat pipe, a vapor chamber, and so on, have be implemented, providing the guaranty for heat dissipation. As a result, the heat-dissipating components have created significant value and profits for manufacturers. The heat dissipation power of the heat-dissipating componets such as the vapor chamber also need to be further improved. CN103542749A discloses a biomimetic wick of the vapor chamber, the wick structure is good for the transmission of working substance and improves the heat dissipation capacity of vaper chamber. However, due to the complicated structure, it needs complicated and expensive devices such as a photolithography device. CN106435665A discloses a wick structure with a natural multi-scale dendritic pin fin copper surface structure of a heat pipe or a vapor chamber prepared by electrochemical deposition, but the structure is easy to cause the working substance to be carried by the air flow, reducing heat dissipation efficiency. Moreover, the porous structure prepared by the electrochemical deposition has weak bonding force with the substrate, poor mechanical strength and the like, which s a significant challenge to the reliability and longevity of the product.

### SUMMARY

Provided herein is a method for preparating a porous wick to overcome the above shortcomings and deficiencies. The method for preparing porous wick comprises the steps of: a) preparing a first electrodeposition electrolyte, which is an aqueous solution comprising 0.5-1.8 mol/L sulfuric acid and 0.1-0.5 mol/L copper sulfate; b) preparing a second electrodeposition electrolyte, which is an aqueous solution comprising 0.2-0.9 mol/L sulfuric acid and 0.4-0.9 mol/L copper sulfate; c) cleaning the surface of a meatal substrate with a mixed solution of a surfactant and a basic compound, activating with dilute hydrochloric acid, and then rinsing; and d) carrying out a first elctrodeposition on the treated substrate in the first electrodeposition electrolyte, and then carrying out the second electrodeposition in the second electrodeposition electrolyte, wherein the second electrodeposition current density is smaller than the first electrodeposition current density.

The disclosure also provides a porous wick prepared by the methods described above. The size of the aperture in the under layer of the porous wick is smaller than that of the above layer, and the aperture wall in the above layer of the porous structure is denser than that of the under layer.

In the disclosure, the porous wick is prepared by electrodepositing twice, as a result that the porous structure is more strong without subsequent sintering, which optimizes the process and saves energy compared to the prior. The method of the disclosure can be applied to various shapes of heat pipe and vapor chamber products, and the thickness of the porous structure can be arbitrarily adjusted above 10 μm, which provides a new direction for the personalized design of the product. By the method of the disclosure, the porous structure with the specific arrangement, excellent capillary force and permeability can be directly obtained on the surface of the substrate, which is good for the transmission of the working liquid.

### BRIEF DESCRIPTION OF THE DRAWINGS

FIG. 1A is an SEM image of a surface of a porous wick prepared in Example 1.

FIG. 1B is an SEM image of a cross section of a porous wick prepared in Example 1.

FIG. 2 is a photograph of the porous wick prepared in Example 1.

FIG. 3 is a comparison diagram of heat-dissipating effects of the porous wick prepared in Example 1 and a copper sheet as vapor chambers, respectively.

### DETAILED DESCRIPTION

The disclosure is described in detail below in conjunction with specific embodiments. However, the protection scope of the disclosure is not limited to the following examples.

### EXAMPLE 1

A certain amount of copper sulfate is weighed and dissolved in deionized water to form a copper sulfate solution, and then an appropriate amount of concentrated sulfuric acid is added to the copper sulfate solution to form a first electrolyte of 0.1 mol/L copper sulfate and 0.5 mol/L sulfuric acid.

A certain amount of copper sulfate is weighed and dissolved in deionized water to form a copper sulfate solution, and then an appropriate amount of concentrated sulfuric acid is added to the copper sulfate solution to form a seconde electrolyte of 0.5 mol/L copper sulfate and 0.2 mol/L sulfuric acid.

The metal substrate is subjected to ultrasonic washing in a mixed solution of sodium dodecylsulphate and sodium hydroxide, and then rinsed with deionized water.

The treated substrate is electrodeposited in the first electrolyte at a constant current density of 0.5 A/cm² for 10 minutes at 25° C.

Then, the product of the first electrodeposition is electrodeposited in the second electrolyte at a constant current density of 0.01 A/cm² for 15 minutes at 20° C.

The resuting porous wick are washed with water.

The porous wick is prepared into a product for heat dissipation test.

### EXAMPLE 2

A first electrolyte is prepared in the same manner as in Example 1 except that the concentration of copper sulfate is 0.5 mol/L and the concentration of sulfuric acid is 1.8 mol/L.

A second electrolyte is prepared in the same manner as in Example 1 except that the concentration of copper sulfate is 0.5 mol/L and the concentration of sulfuric acid is 0.2 mol/L.

The substrate is pretreated in the same manner as in Example 1.

The treated substrate is electrodeposited in the first electrolyte at a constant current density of 0.8 A/cm² for 20 seconds at 25° C.

Then, the product of the first electrodeposition is electrodeposited in the second electrolyte at a constant current density of 0.02 A/cm² for 10 minutes at 20° C.

The resuting porous wick is washed with water.

### EXAMPLE 3

A first electrolyte is prepared in the same manner as in Example 1 except that the concentration of copper sulfate is 0.2 mol/L and the concentration of sulfuric acid is 0.8 mol/L.

A second electrolyte is prepared in the same manner as in Example 1 except that the concentration of copper sulfate is 0.4 mol/L and the concentration of sulfuric acid is 0.2 mol/L.

The substrate is pretreated in the same manner as in Example 1.

The treated substrate is electrodeposited in the first electrolyte at a constant current density of 1.5 A/cm² for 50 seconds at 25° C.

Then, the product of the first electrodeposition is electrodeposited in the second electrolyte at a constant current density of 0.05 A/cm² for 10 minutes at 20° C. .

The resuting porous wick is washed with water.

### EXAMPLE 4

A first electrolyte is prepared in the same manner as in Example 1 except that the concentration of copper sulfate is 0.1 mol/L and the concentration of sulfuric acid is 0.9 mol/L.

A second electrolyte is prepared in the same manner as in Example 1 except that the concentration of copper sulfate is 0.9 mol/L and the concentration of sulfuric acid is 0.9 mol/L.

The substrate is pretreated in the same manner as in Example 1.

The treated substrate is electrodeposited in the first electrolyte at a constant current density of 5.0 A/cm² for 20 seconds at 25° C.

Then, the product of the first electrodeposition is electrodeposited in the second electrolyte at a constant current density of 0.1 A/cm² for 10 minutes at 20° C.

The resuting porous wick is washed with water.

### EXAMPLE 5

A first electrolyte is prepared in the same manner as in Example 1 except that the concentration of copper sulfate is 0.3 mol/L and the concentration of sulfuric acid is 0.7 mol/L.

A second electrolyte is prepared in the same manner as in Example 1 except that the concentration of copper sulfate is 0.5 mol/L and the concentration of sulfuric acid is 0.2 mol/L.

The substrate is pretreated in the same manner as in Example 1.

The treated substrate is electrodeposited in the first electrolyte at a constant current density of 1.0 A/cm² for 90 seconds at 25° C.

Then, the product of the first electrodeposition is electrodeposited in the second electrolyte at a constant current density of 0.08 A/cm² for 5 minutes at 20° C.

The resuting porous wick is washed with water.

### EXAMPLE 6

A first electrolyte is prepared in the same manner as in Example 1 except that the concentration of copper sulfate is 0.45 mol/L and the concentration of sulfuric acid is 0.55 mol/L.

A second electrolyte is prepared in the same manner as in Example 1 except that the concentration of copper sulfate is 0.5 mol/L and the concentration of sulfuric acid is 0.2 mol/L.

The substrate is pretreated in the same manner as in Example 1.

The treated substrate is electrodeposited in the first electrolyte at a constant current density of 1.0 A/cm² for 10 seconds at 25° C.

Then, the product of the first electrodeposition is electrodeposited in the second electrolyte at a constant current density of 0.05 A/cm² for 10 minutes at 20° C.

The resuting porous wick is washed with water.

### COMPARATIVE EXAMPLE 1

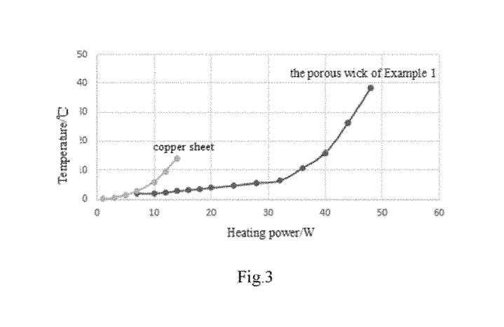

The same heat-dissipating effect test is performed on the same sized copper sheet and the porous wick prepared in Example 1. The results are shown in FIG. 3.

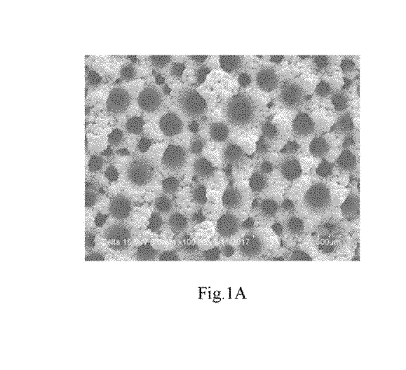

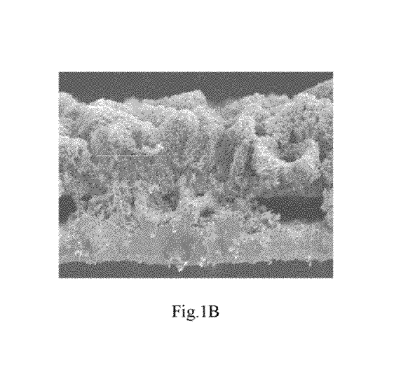

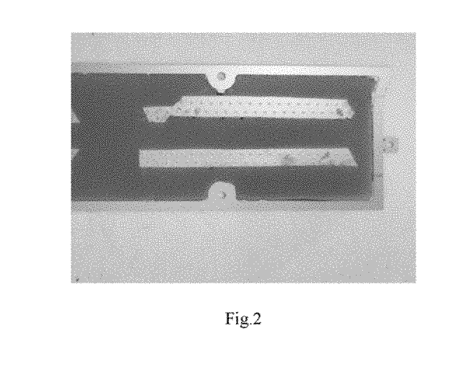

FIG. 1A is an SEM image of a surface of a porous wick prepared in Example 1, and FIG. 1B is an SEM image of a cross section of a porous wick prepared in Example 1. As can be seen from the figures, the above layer of the porous wick is denser and the under layer is looser, which is good for the transmission of the working liquid. As can be seen from FIG. 1A and FIG. 1B, the pores of the porous structure are uniformly distributed, the porosity is high, and the structure's mechanical strength is strong. FIG. 2 is a photograph of the porous wick prepared in Example 1, the dark part of the figure is a porous structure prepared by the disclosure. It can be seen from the figure that the porous structure is well combined with the substrate and can be prepared into any shape. FIG. 3 is a comparison diagram of heat-dissipating effects of the porous wick prepared in Example 1 and a copper sheet as vapor chambers, respectively, the copper sheet of Comparative Example 1 and the porous wick of Example 1 are measured in the same manner. It can be seen from FIG. 3 that the heat-dissipating effect of the porous wick of Example 1 is much higher than that of Comparative Example 1, and the heat-dissipating effect of the porous wick of Example 1 is excellent.

For the other embodiments provided by the disclosure, the characteristics of the obtained produc are the same as or similar to those in Example 1, and are not described in detail herein.

Of course, the disclosure may have other various embodiments. Without departing from the spirit and essence of the disclosure, those skilled in the art can make various corresponding changes and modifications according to the disclosure, but these corresponding changes and variations shall fall within the scope of the appended claims of the disclosure.

What is claimed is:

1. A method for preparing a porous wick, comprising the steps of:
a) preparing an electrolyte, which is an aqueous solution comprising 0.5-1.8 mol/L sulfuric acid and 0.1-0.5 mol/L copper sulfate;
b) preparing a second electrodeposition electrolyte, which is an aqueous solution comprising 0.2-0.9 mol/L sulfuric acid and 0.4-0.9 mol/L copper sulfate;
c) cleaning the surface of a metal substrate with a mixed solution of a surfactant and a basic compound, activating with dilute hydrochloric acid, and then rinsing; and
d) carrying out a first elctrodeposition on the treated substrate in the first electrodeposition electrolyte, and then carrying out the second electrodeposition in the second electrodeposition electrolyte, wherein the second electrodeposition current density is smaller than the first electrodeposition current density.

2. The method for preparing a porous wick according to the claim 1, wherein the molar concentration ratio of sulfuric acid to copper sulfate in the first electrodeposition eletrolyte is 5.5:4.5-9:1.

3. The method for preparing a porous wick according to the claim 2, wherein the molar concentration ratio of sulfuric acid to copper sulfate in the first electrodeposition eletrolyte is 7:3-8:2.

4. The method for preparing a porous wick according to the claim 1, wherein the first electrodeposition current density is 0.5-5 A/cm², and the electrodeposition time is 10 seconds-10 minutes.

5. The method for preparing a porous wick according to the claim 4, wherein the first electrodeposition current density is 0.8-1.5 A/cm², and the electrodeposition time is 50-90 seconds.

6. The method for preparing a porous wick according to the claim 1, wherein the second electrodeposition current density is 0.01-0.1 A/cm², and the electrodeposition time is 5-15 minutes.

7. The method for preparing a porous wick according to the claim 6, wherein the second electrodeposition current density is 0.02-0.05 A/cm², and the electrodeposition time is 10-15 minutes.

8. A porous wick, being propared by the method according to claim 1, wherein the size of the aperture in the under layer of the porous wick is smaller than that of the above layer, and the aperture wall in the above layer of the porous structure is denser than that of the under layer.
